(19) United States
(12) Patent Application Publication
(10) Pub. No.: US 2013/0224455 A1
(43) Pub. Date: Aug. 29, 2013

(54) DISPLAY SUBSTRATE HAVING A BLOCKING LAYER

(71) Applicants: SEUNG-MIN LEE, Jeju-si (KR); Hyeong-Suk Yoo, Yongin-si (KR); Ki-Beom Lee, Seoul (KR); Seung-Jun Lee, Yongin-si (KR); Jae-Hyuk Chang, Seongnam-si (KR)

(72) Inventors: SEUNG-MIN LEE, Jeju-si (KR); Hyeong-Suk Yoo, Yongin-si (KR); Ki-Beom Lee, Seoul (KR); Seung-Jun Lee, Yongin-si (KR); Jae-Hyuk Chang, Seongnam-si (KR)

(21) Appl. No.: 13/540,209

(22) Filed: Jul. 2, 2012

(30) Foreign Application Priority Data
Feb. 29, 2012 (KR) 10-2012-0021193

(51) Int. Cl. B32B 7/02; B32B 27/08; C23C 14/34; B32B 27/06; B05D 5/06; C23C 16/44

(52) U.S. Cl. 428/213; 427/162; 204/192.1; 428/480; 428/483; 428/516; 428/446; 428/451; 428/448

(57) ABSTRACT

A method for manufacturing a display substrate includes forming a plastic base substrate. A blocking layer is formed on a surface of the plastic base substrate by depositing a first material and a second material that are distinct. A substrate includes a plastic base substrate and a blocking layer formed at surfaces of the plastic base substrate and having a first layer and a second layer alternatingly. The first layer and second layer include continuously changing component ratio of a first material to a second material. The blocking layer effectively blocks moisture and/or oxygen.

### CROSS-REFERENCE TO RELATED APPLICATION

This application claims priority under 35 U.S.C. §119 to Korean Patent Application No. 10-2012-0021193, filed on Feb. 29, 2012, in the Korean Intellectual Property Office (KIPO), the contents of which are herein incorporated by reference in their entireties.

### FIELD OF THE DISCLOSURE

Exemplary embodiments of the present invention relate to a display substrate. More particularly, exemplary embodiments of the present invention relate to a display substrate having a blocking layer and a method for manufacturing the same.

### DISCUSSION OF THE RELATED ART

Flat panel displays (FPDs) are in use today. FPDs have traditionally been rigid and to some extent, fragile. However, some modern FPDs are considered to be flexible displays. The flexible display includes an organic electroluminescence (EL) or an organic thin film transistor (TFT) implemented on a flexible substrate to produce a flexible thin-film transistor liquid crystal display (TFT-LCD), passive matrix (PM) LCD, an electrical paper and so on. The flexible display need not remain flexible after manufacturing and integration, but may, at some point in the manufacturing process, be capable of conforming to a desired shape that is not planar. The flexible substrate can include thin film shaped glass and a metal plate, however, the flexible substrate often includes a plastic substrate that may be easily-shaped, having low-weight and adaptability for sequence processes.

The flexible display substrate may have certain characteristics typically found within the conventional display. While a plastic substrate may offer the above-mentioned features, a glass substrate may offer greater chemical resistance, greater thermal resistance, decreased hygroscopicity, and/or decreased permeability.

### SUMMARY OF THE INVENTION

Exemplary embodiments of the present invention provide a display substrate having a blocking layer and a method for manufacturing a substrate.

According to an exemplary embodiment of the present invention, a method for manufacturing a substrate includes forming a plastic base substrate and forming a blocking layer on a surface of the plastic base substrate by depositing a first material and a second material.

In an exemplary embodiment, a component ratio of the first material to the second material may be changed according to a height of the plastic base substrate.

In an exemplary embodiment, the method may further include a first layer having the first material and a second layer having the second material. The first layer and the second layer may be formed alternatingly.

In an exemplary embodiment, the first material may include organic material, and the second material comprises inorganic material.

In an exemplary embodiment, the first material may include polyacrylate, polyethylene naphthalate (PEN) or polyethylene terephthalte (PET).

In an exemplary embodiment, the second material may include silicon oxide (SiO₂) or aluminum oxide (Al₂O₃).

In an exemplary embodiment, the first material and the second material may be supplied from at least two more sources respectively, and the component ratio of the first material to the second material may be adjusted by controlling the sources.

In an exemplary embodiment, the blocking layer may be formed by a sputtering method, and the blocking layer may be formed by sputtering the first material and the second material simultaneously.

In an exemplary embodiment, the blocking layer may be formed by a chemical vapor deposition (CVD) method, and the blocking layer may be formed by adjusting the component ratio of the first material to the second material.

In an exemplary embodiment, the plastic base substrate may be moved along a first direction, and a plurality of sources may be disposed along the first direction, and the first material and the second material may be supplied from a plurality of the sources.

In an exemplary embodiment, the blocking layer may be formed by a sputtering method, and the sources may supply the first material and the second material alternatingly.

In an exemplary embodiment, the blocking layer may be formed by a chemical vapor deposition (CVD) method, and the sources may supply the first material and the second material alternatingly.

In an exemplary embodiment, the sources may be disposed spaced apart from each other by different distances, and each of the distances may be increased according to each of thicknesses of the first layer and the second layer.

In an exemplary embodiment, the first layer may be formed substantially thicker than the second layer.

In an exemplary embodiment, thicknesses of the first layer may be constant, and thicknesses of the second layer may be increased according to a height of the plastic base substrate.

According to an exemplary embodiment of the present invention, a substrate includes a plastic base substrate and a blocking layer foamed at surfaces of the plastic base substrate and having a first layer and a second layer alternatingly. The first layer and second layer include continuously changing component ratio of a first material to a second material.

In an exemplary embodiment, the first material may include organic material, and the second material may include inorganic material.

In an exemplary embodiment, the first material may include polyacrylate, polyethylene naphthalate (PEN) or polyethylene terephthalte (PET).

In an exemplary embodiment, the second material may include silicon oxide (SiO₂) or aluminum oxide (Al₂O₃).

In an exemplary embodiment, the first layer may be formed substantially thicker than the second layer.

In an exemplary embodiment, thicknesses of the first layer may be constant, and thicknesses of the second layer may be increased according to a height of the plastic base substrate.

According to the present invention, organic layers and inorganic layers of a blocking layer, which is formed on a base substrate, have continuously changing component ratio according to a height of the base substrate in manufacturing a flexible substrate. Thus, a discontinuous area does not exist between the organic layer and the inorganic layer of the blocking layer. The adhesive power between the organic layer and the inorganic layer may be increased. Thus, the blocking layer blocking moisture or oxygen effectively may be formed on the base substrate of the flexible substrate.

In addition, the organic layer of the blocking layer is formed thicker as the height from the base substrate is increased. The crack of the substrate may be prevented more effectively when the flexible substrate is bent. Thus, moisture or oxygen is blocked effectively.

A method for manufacturing a display substrate according to an exemplary embodiment of the present invention includes forming a plastic base substrate. A first material is deposited on at least one surface of the base substrate without depositing a second material creating a first layer composed entirely of the first material. The first and second materials are simultaneously deposited onto the first layer creating an intermediate layer comprising both the first and second materials. The second material is deposited on the intermediate layer without depositing the first material creating a second layer comprised entirely of the second material. The first material and the second material are distinct materials. The first, intermediate, and second layers together define a blocking layer blocking moisture and oxygen.

### BRIEF DESCRIPTION OF THE DRAWINGS

The above and other features of the present invention will become more apparent by describing in detail exemplary embodiments thereof with reference to the accompanying drawings, in which:

FIG. 1 is a cross-sectional view illustrating a substrate in accordance with an exemplary embodiment of the present invention;

FIG. 2 is an enlarged cross-sectional view illustrating a blocking layer of the substrate in FIG. 1;

FIG. 3 is a graph illustrating stress distribution according to a height of the substrate in FIG. 1;

FIG. 4 is a cross-sectional view illustrating a part of the blocking layer of the substrate in FIG. 1;

FIG. 5 is a cross-sectional view illustrating a method for manufacturing a substrate in accordance with an exemplary embodiment of the present invention;

FIG. 6 is a cross-sectional view illustrating a method for manufacturing a substrate in accordance with an exemplary embodiment of the present invention;

FIG. 7 is a cross-sectional view illustrating a method for manufacturing a substrate in accordance with an exemplary embodiment of the present invention;

FIG. 8 is a cross-sectional view illustrating a method for manufacturing a substrate in accordance with an exemplary embodiment of the present invention;

FIG. 9 is a cross-sectional view illustrating a method for manufacturing a substrate in accordance with an exemplary embodiment of the present invention;

FIG. 10 is a cross-sectional view illustrating a method for manufacturing a substrate in accordance with an exemplary embodiment of the present invention;

FIG. 11 is a partial cross-sectional view illustrating a substrate in accordance with an exemplary embodiment of the present invention.

### DETAILED DESCRIPTION

Hereinafter, exemplary embodiments of the present invention will be explained in detail with reference to the accompanying drawings.

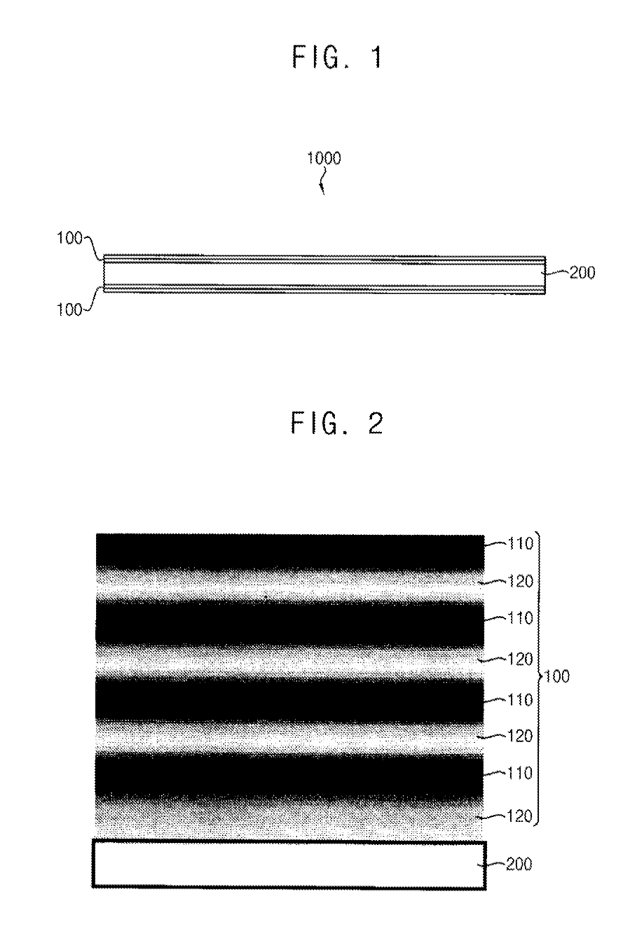

FIG. 1 is a cross-sectional view illustrating a substrate in accordance with an exemplary embodiment of the present invention.

Referring to FIG. 1, a substrate 1000 includes a blocking layer 100 and a base substrate 200. The base substrate 200 includes plastic. The blocking layer 100 is formed at opposing sides of the base substrate 200. For example, the blocking layer 100 is formed at an upper surface of the base substrate 200 and a lower surface of the substrate 200. The blocking layer 100 supplements permeability of the base substrate 200. Since the base substrate 200 includes the plastic material, the base substrate 200 has permeability for moisture or oxygen. The blocking layer 100 blocks the oxygen or the moisture, and the blocking layer 100 prevents the oxygen or the moisture from passing through the base substrate 200.

FIG. 2 is an enlarged cross-sectional view illustrating a blocking layer of the substrate in FIG. 1.

Referring to FIG. 2, the blocking layer 100 of the is formed on the base substrate 200. The blocking layer 100 is formed by depositing a plurality of layers. The blocking layer 100 includes a first layer 110 having a first material and a second layer 120 having a second material. The blocking layer 100 is formed by depositing a layer with the first material and the second material at continuously changing ratios.

The second layer 120 having the second material is formed on the base substrate 200, and the first layer 110 having the first material is formed on the second layer 120. Repeatedly, the second layer 120 having the second material is formed on the first layer 110 having the first material, and the first layer 110 having the first material is formed on the second layer 120. The component materials of the first layer 110 and the second layer 120 is not changed discontinuously, and the component materials of the first and second layers 110 and 120 are changed continuously with each additional layer. Thus, the boundary between the first layer 110 and the second layer 120 is not shaped clearly.

Since the boundary between the first layer 110 and the second layer 120 is not shaped clearly, the adhesion power between the first layer 110 and the second layer 120 is stronger than where the boundary is shaped clearly. Thus, cracking, which might be formed between the first layer 110 and the second layer 120, may be diminished.

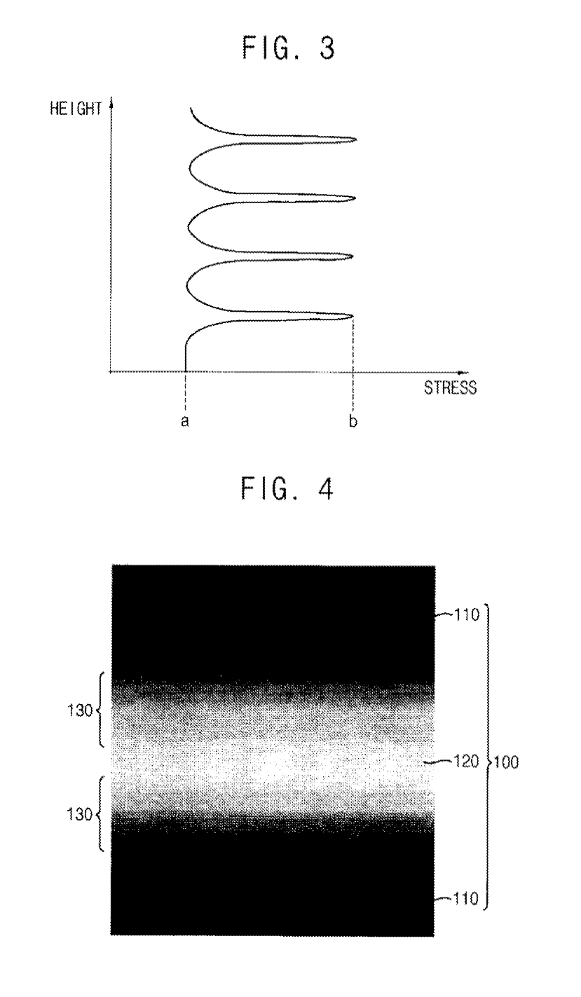

FIG. 3 is a graph illustrating stress distribution according to a height of the substrate in FIG. 1.

Referring to FIG. 3, the stress distribution according to the height of the substrate is illustrated. The first layer is a part a, which relatively weak stress is applied to. The second layer is a part b, which relatively strong stress is applied to. Referring to the graph, the change from the first layer a to the second layer b is continuous. The first layer a is an area including the first material, and the second layer b is an area including the second material. The middle area between the first layer a and the second layer b includes both of the first material and the second material. In the middle area between the first layer a and the second layer b, the component ratio of the first material to the second material is changed continuously. When the component ratio of the first material to the second material is changed discontinuously, the adhesive power is degraded at the discontinuous area. When the external stress is applied, the crack may occur firstly at the discontinuous area. The discontinuous area for the component ratio of the first material to the second material between the first layer a and the second layer b is not included.

FIG. 4 is a cross-sectional view illustrating a part of the blocking layer of the substrate in FIG. 1.

Referring to FIG. 4, the blocking layer 100 includes a first layer 110, a second layer 120 and a continuous change area 130. The continuous change area 130 is disposed between the first layer 110 and the second layer 120. The first layer 110 includes a first material but not a second material, and the second layer 120 includes the second material but not the first material. The continuous change area 130 includes both of the first material and the second material. In the continuous change area 130, some area includes only the first material, and the other area includes only the second material. In the continuous change area 130, the first material and the second material are mixed, and the component ratio is changed according to the height. Since the component ratio of the first material to the second material is changed continuously, the boundary between the first material and the second material is not formed clearly in the continuous change area 130.

The height of the continuous change area 130 may be changed. The height of the continuous change area 130 may be decided according to the adhesive power between the first layer 110 and the second layer 120 or the permeability of the blocking layer 100.

The first material includes an organic material. The second material includes an inorganic material. The first material may include polyacrylate, polyethylene naphthalate (PEN), polyethylene terephthalte (PET). The second material may include oxide silicon (SiO₂), aluminum oxide (Al₂O₃).

The moisture or the oxygen might diffuse through the crack formed at the inorganic layer having the inorganic material. The organic layer having the organic material prevents the moisture of the oxygen from the penetration into the base substrate by increasing the diffusing distance. The organic layer is the first layer. The inorganic layer is the second layer. The first layer 110 may be formed thicker than the second layer 120. Since the stress distribution may be changed according to the height of the substrate, the thickness of the first layer 110 may be changed according to the height of the substrate.

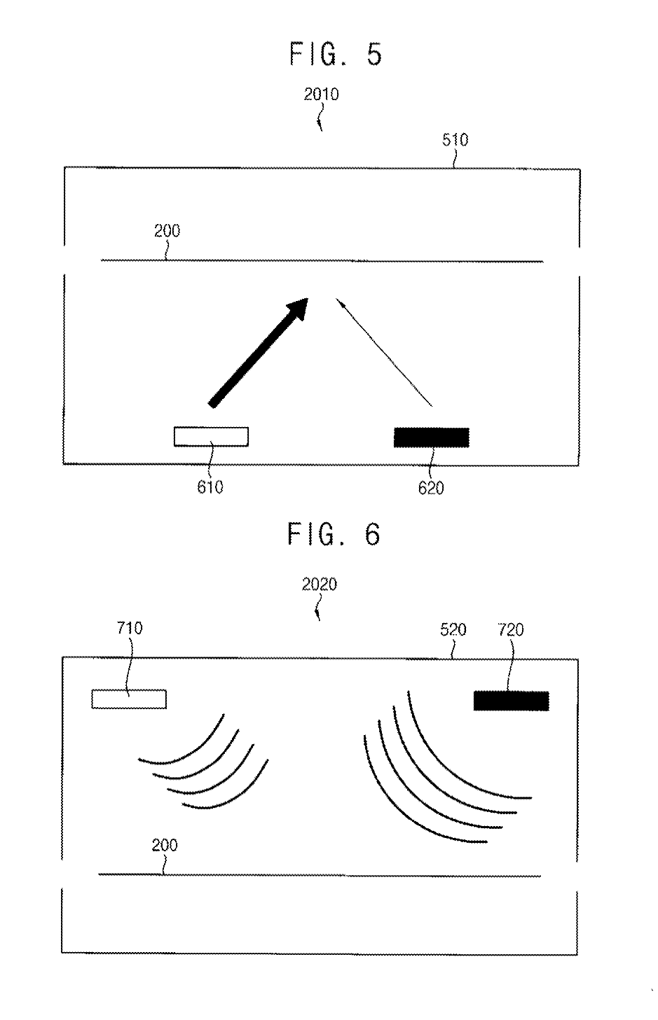

FIG. 5 is a cross-sectional view illustrating a method for manufacturing a substrate in accordance with an exemplary embodiment of the present invention.

Referring to FIG. 5, the manufacturing apparatus 2010 includes a chamber 510, a first source 610 and a second source 620. The chamber 510 provides a vacuum condition for depositing a layer on the base substrate 200. In the chamber 510, the first source 610 and the second source 620 are disposed. The first source 610 and the second source 620 are used simultaneously for depositing a thin layer on the base substrate 200.

The first source 610 and the second source 620 of the present embodiment form a layer on the base substrate 200 by a sputtering method. According to a sputtering yield, an effective thickness, a surface roughness, an optical transmittancy of the materials used in the first source 610 and the second source 620, the blocking layer is formed by changing individual powers of the first source 610 and the second source 620.

Since the base substrate 200 is fixed in the chamber 510, the component ratio of the first material to the second material is adjusted by controlling the first source 610 and the second source 620. Thus, according to a kind of forming layer, only the first source 610 may be activated in some cases, or only the second source 620 may be activated in other cases. Both of the first source 610 and the second source 620 may be activated in yet other cases. The changes of the first layer and the second layer including the first material and the second material may be formed by simultaneous sputtering the first source 610 and the second source 620 on the base substrate 200 and controlling the intensities of the first source 610 and the second sources 620. Thus, the blocking layer having the changing component ratio of the first material to the second material according to the height may be formed.

FIG. 6 is a cross-sectional view illustrating a method for manufacturing a substrate in accordance with an exemplary embodiment of the present invention.

Referring to FIG. 6, the manufacturing apparatus 2020 includes a chamber 520, a fist source 710 and a second source 720. The chamber 520 provides a vacuum condition for depositing a layer on the base substrate 200. In the chamber 520, the first source 710 and the second source 720 are disposed. The first source 710 and the second source 720 are used simultaneously for depositing a thin layer on the base substrate 200.

The first source 710 and the second source 720 form a layer on the base substrate 200 by a chemical vapor deposition (CVD) method. According to a boiling point, an effective thickness, a surface roughness, an optical transmittancy of the materials used in the first source 710 and the second source 720, the blocking layer is formed by changing individual powers of the first source 710 and the second source 720.

Since the base substrate 200 is fixed in the chamber 520, the component ratio of the first material to the second material is adjusted by controlling the first source 710 and the second source 720. Thus, according to a kind of forming layer, only the first source 710 may be activated in some cases, or only the second source 720 may be activated in other cases. Both of the first source 710 and the second source 720 may be activated in still other cases. The changes of the first layer and the second layer including the first material and the second material may be formed by simultaneous sputtering the first source 710 and the second source 720 on the base substrate 200 and controlling the intensities of the first source 710 and the second sources 720. Thus, the blocking layer having the changing component ratio of the first material to the second material according to the height may be formed.

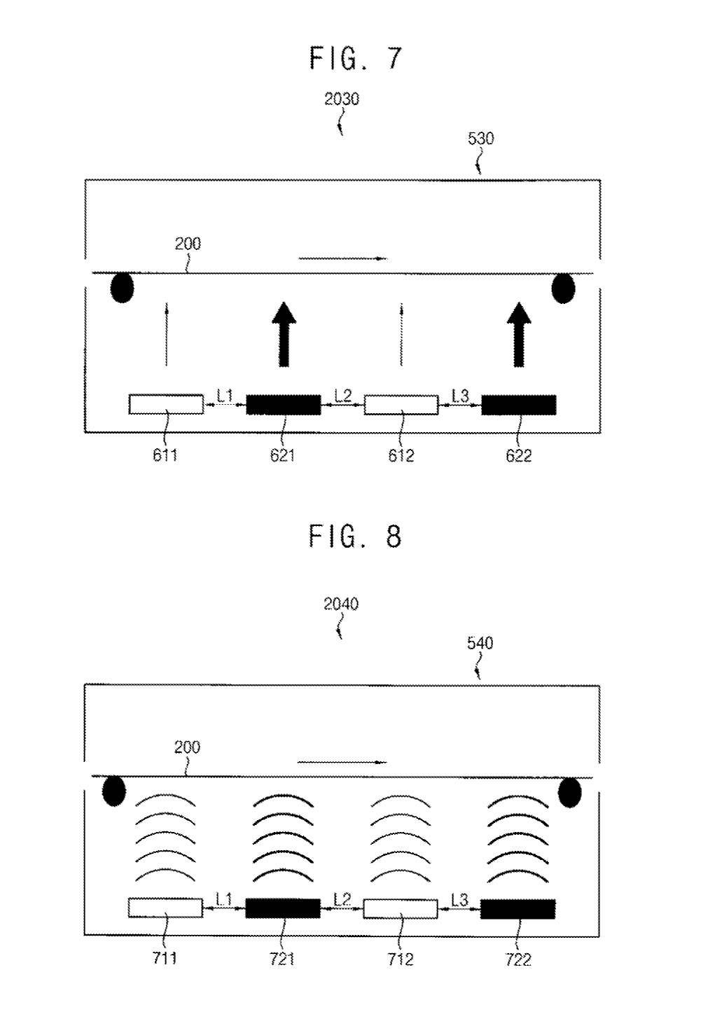

FIG. 7 is a cross-sectional view illustrating a method for manufacturing a substrate in accordance with an exemplary embodiment of the present invention.

Referring to FIG. 7, the manufacturing apparatus 2030 includes a chamber 530, first sources 611, 612 and second sources 621, 622. The chamber 530 provides a vacuum condition for depositing a layer on the base substrate 200. A layer is deposited on the base substrate 200 as the base substrate 200 is moved. In the chamber 530, the first sources 611, 612 and the second sources 621, 622 are disposed. Where desired, a plurality of the first sources and the second sources may be disposed along the moving direction of the base substrate 200. The first sources 611, 612 and the second sources 621, 622 are used simultaneously for depositing a thin layer on the base substrate 200.

The first sources 611, 612 and the second sources 621, 622 form a layer on the base substrate 200 by a sputtering method. The first sources 611, 612 and the second sources 621, 622 are disposed alternatingly. When the first sources 611, 612 and the second sources 621, 622 are disposed alternatingly, the first layer and the second layer are formed alternatingly according to the movement of the base substrate 200.

According to a sputtering yield, an effective thickness, a surface roughness, an optical transmittancy of the materials used in the first sources 611, 612 and the second sources 621, 622, the blocking layer is formed by changing individual powers of the first sources 611, 612 and the second sources 621, 622. In addition, the blocking layer may be formed by maintaining the individual powers of the first sources 611, 612 and the second sources 621, 622 and moving the base substrate 200 in a constant direction.

Since the base substrate 200 is moved in the constant direction, a point of the base substrate 200 is affected by the first sources 611, 612 and the second sources 621, 622 by moving the base substrate 200 when the first sources 611, 612 and the second sources 621, 622 are disposed along the moving direction of the base substrate 200.

Thus, the materials supplied by the first sources 611, 612 and the second sources 621, 622 are deposited alternatingly at the same point.

The height of the layer, which is deposited on the base substrate 200, may be adjusted by controlling source distances L1, L2, L3. The source distances L1, L2, L3 are distances between the first sources 611, 612 and the second sources 621, 622. For example, the source distances L1, L2, L3 may be substantially the same as each other.

Moreover, the height of the layer may be adjusted by controlling the powers of the first sources 611, 612 and the second sources 621, 622. The intensities of the first sources 611, 612 and the second sources 621, 622 are illustrated differently. The intensities may be adjusted according to environmental conditions such as a thickness of the material for the base substrate 200.

FIG. 8 is a cross-sectional view illustrating a method for manufacturing a substrate in accordance with an exemplary embodiment of the present invention.

Referring to FIG. 8, the manufacturing apparatus 2040 includes a chamber 540, first sources 711, 712 and second sources 721, 722. The chamber 540 provides a vacuum condition for depositing a layer on the base substrate 200. A layer is deposited on the base substrate 200 as the base substrate 200 is moved. In the chamber 540, the first sources 711, 712 and the second sources 721, 722 are disposed. Where desired, a plurality of the first sources and the second sources may be disposed along the moving direction of the base substrate 200. The first sources 711, 712 and the second sources 721, 722 are used simultaneously for depositing a thin layer on the base substrate 200.

The first sources 711, 712 and the second sources 721, 722 form a layer on the base substrate 200 by a chemical vapor deposition (CVD) method. The first sources 711, 712 and the second sources 721, 722 are disposed alternatingly. When the first sources 711, 712 and the second sources 721, 722 are disposed alternatingly, the first layer and the second layer are formed alternatingly according to the movement of the base substrate 200.

According to a boiling point, an effective thickness, a surface roughness, an optical transmittancy of the materials used in the first sources 711, 712 and the second sources 721, 722, the blocking layer is formed by changing individual powers of the first sources 711, 712 and the second sources 721, 722. In addition, the blocking layer may be formed by maintaining the individual powers of the first sources 711, 712 and the second sources 721, 722 and moving the base substrate 200 in a constant direction.

Since the base substrate 200 is moved in the constant direction, a point of the base substrate 200 is affected by the first sources 711, 712 and the second sources 721, 722 by moving the base substrate 200 when the first sources 711, 712 and the second sources 721, 722 are disposed along the moving direction of the base substrate 200. When a layer is deposited by the CVD method, a depositing point may not be targeted clearly. Where desired, separate devices may be used for separating the sources in the chamber 540. Thus, the materials supplied by the first sources 711, 712 and the second sources 721, 722 are deposited alternatingly at the same point.

The height of the layer, which is deposited on the base substrate 200, may be adjusted by controlling source distances L1, L2, L3. The source distances L1, L2, L3 are distances between the first sources 711, 712 and the second sources 721, 722. For example, the source distances L1, L2, L3 may be substantially the same as each other.

Moreover, the height of the layer may be adjusted by controlling the powers of the first sources 711, 712 and the second sources 721, 722. The intensities of the first sources 711, 712 and the second sources 721, 722 are illustrated differently. The intensities may be adjusted according to environmental conditions such as a thickness of the material for the base substrate 200.

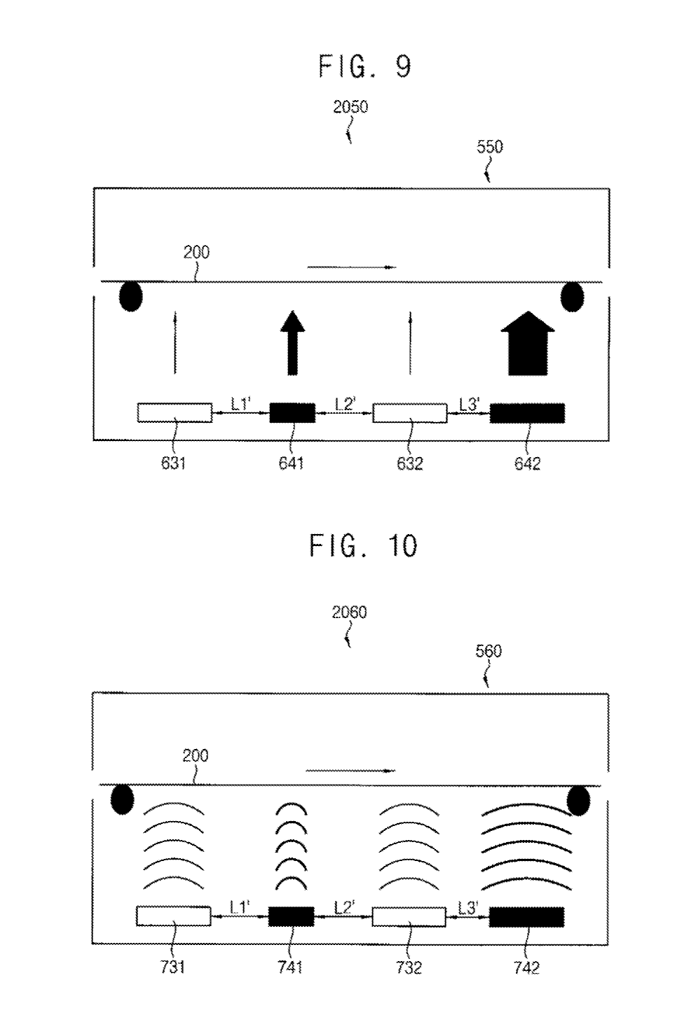

FIG. 9 is a cross-sectional view illustrating a method for manufacturing a substrate in accordance with an exemplary embodiment of the present invention.

The components illustrated in FIG. 9 are substantially the same as described above with respect to in FIG. 7 except the first sources 631, 632, the second sources 641, 642 and the source distances L1, L2, L3. Thus, the repeated description will be omitted.

Referring to FIG. 9, the manufacturing apparatus 2050 includes a chamber 550, first sources 631, 632 and second sources 641, 642. A layer is deposited on the base substrate 200 as the base substrate 200 is moved. The first sources 631, 632 and the second sources 641, 642 are used simultaneously for depositing a thin layer on the base substrate 200.

The first sources 631, 632 and the second sources 641, 642 form a layer on the base substrate 200 by a sputtering method. The first sources 631, 632 and the second sources 641, 642 are disposed alternatingly. When the first sources 631, 632 and the second sources 641, 642 are disposed alternatingly, the first layer and the second layer are formed alternatingly according to the movement of the base substrate 200.

According to a sputtering yield, an effective thickness, a surface roughness, an optical transmittancy of the materials used in the first sources 631, 632 and the second sources 641, 642, the blocking layer is formed by changing individual powers of the first sources 631, 632 and the second sources 641, 642. In addition, the blocking layer may be formed by maintaining the individual powers of the first sources 631, 632 and the second sources 641, 642 and moving the base substrate 200 in a constant direction.

Since the base substrate 200 is moved in the constant direction, a point of the base substrate 200 is affected by the first sources 631, 632 and the second sources 641, 642 by moving the base substrate 200 when the first sources 631, 632 and the second sources 641, 642 are disposed along the moving direction of the base substrate 200. Thus, the materials supplied by the first sources 631, 632 and the second sources 641, 642 are deposited alternatingly at the same point.

The height of the layer, which is deposited on the base substrate 200, may be adjusted by controlling source distances L1′, L2′, L3′. The source distances L1′, L2′, L3′ are distances between the first sources 631, 632 and the second sources 641, 642. Where desired, the heights of the first layer and the second layer may be formed differently according to the height. For example, when the height of the first layers may be getting thicker as the height gets higher, the first layer formed thicker endures greater stress at the higher height as the base substrate 200 is bent. To form layers having the different heights, the blocking layer 100 may be formed by adjusting the source distances L1′, L2′, L3′ and the intensities of the first sources 631, 632 and the second sources 641, 642. The source distances may be used for adjusting the thickness of the first layer and the second layer of the blocking layer 100.

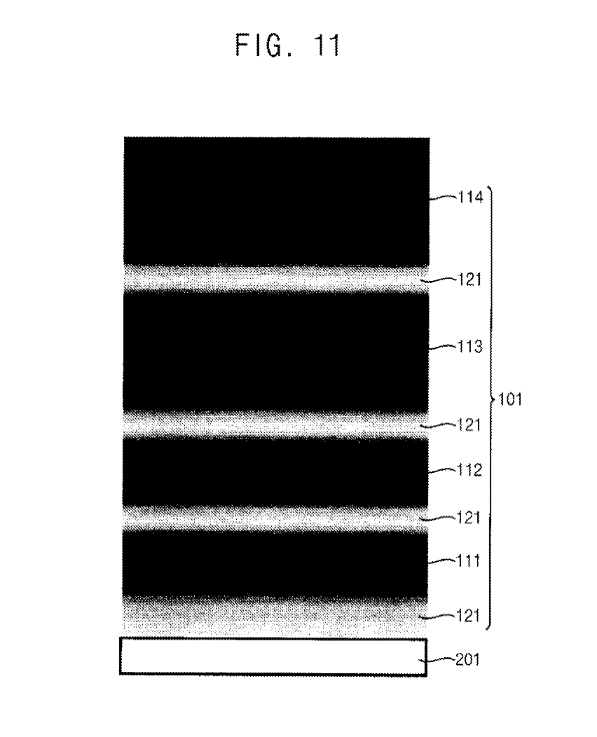

FIG. 10 is a cross-sectional view illustrating a method for manufacturing a substrate in accordance with an exemplary embodiment of the present invention.

The components of the present invention illustrated in FIG. 10 are substantially the same as those described above with respect to FIG. 8 except the first sources 731, 732, the second sources 741, 742 and the source distances L1, L2, L3. Thus, the repeated description will be omitted.

Referring to FIG. 10, the manufacturing apparatus 2060 includes a chamber 560, first sources 731, 732 and second sources 741, 742. A layer is deposited on the base substrate 200 as the base substrate 200 is moved. The first sources 731, 732 and the second sources 741, 742 are used simultaneously for depositing a thin layer on the base substrate 200.

The first sources 731, 732 and the second sources 741, 742 form a layer on the base substrate 200 by a chemical vapor deposition (CVD) method. The first sources 731, 732 and the second sources 741, 742 are disposed alternatingly. When the first sources 731, 732 and the second sources 741, 742 are disposed alternatingly, the first layer and the second layer are formed alternatingly according to the movement of the base substrate 200.

According to a boiling point, an effective thickness, a surface roughness, an optical transmittancy of the materials used in the first sources 731, 732 and the second sources 741, 742, the blocking layer is formed by changing individual powers of the first sources 731, 732 and the second sources 741, 742. In addition, the blocking layer may be formed by maintaining the individual powers of the first sources 731, 732 and the second sources 741, 742 and moving the base substrate 200 in a constant direction.

Since the base substrate 200 is moved in the constant direction, a point of the base substrate 200 is affected by the first sources 731, 732 and the second sources 741, 742 by moving the base substrate 200 when the first sources 731, 732 and the second sources 741, 742 are disposed along the moving direction of the base substrate 200.

When a layer is deposited by the CVD method, a depositing point may not be targeted clearly. Where desired, separate devices may be used for separating the sources in the chamber 560. Thus, the materials supplied by the first sources 731, 732 and the second sources 741, 742 are deposited alternatingly at the same point.

The height of the layer, which is deposited on the base substrate 200, may be adjusted by controlling source distances L1′, L2′, L3′. The source distances L1′, L2′, L3′ are distances between the first sources 731, 732 and the second sources 741, 742. Where desired, the heights of the first layer and the second layer may be formed differently according to the height. For example, when the height of the first layers may be getting thicker as the height gets higher, the first layer formed thicker endures greater stress at the higher height as the base substrate 200 is bent. To form layers having the different heights, the blocking layer 100 may be formed by adjusting the source distances L1′, L2′, L3′ and the intensities of the first sources 731, 732 and the second sources 741, 742. The source distances may be used for adjusting the thickness of the first layer and the second layer of the blocking layer 100.

FIG. 11 is a partial cross-sectional view illustrating a substrate in accordance with an exemplary embodiment of the present invention.

Referring to FIG. 11, the substrate includes a base substrate 201 and a blocking layer 101. The blocking layer 101 is substantially the same as the blocking layer 100 as discussed above with respect to FIG. 2 except that the thicknesses of the first layers 111, 112, 113, 114 are changed according to the distance from the base substrate 201. The repeated description will be omitted.

The blocking layer 101 is formed on the base substrate 201. The blocking layer 101 is formed by depositing a plurality of layers. The blocking layer 101 includes first layers 111, 112, 113, 114 having a first material and second layers 121 having a second material.

The first layers 111, 112, 113, 114 have better endurance over the stress than the second layer. Thus, the first layers endure more stress than the second layers. When the flexible substrate is bent, the substrate forms a fan shape. When the flexible substrate formed the fan shape, the maximum stress is applied to the top area or the bottom area of the flexible substrate. The most stress is applied to the most deformed area. Thus, the stress distribution is changed according to the height.

When the blocking layer 101 is formed at the base substrate 201, the higher layer from the bent base substrate 201 has more stress among a plurality of layers of the blocking layer 101. Thus, the thicknesses of the first layers 111, 112, 113, 114 may be adjusted so that the higher layer from the base substrate 201 has more endurance for the stress.

Referring to FIG. 11, as the height from the base substrate 201 increases, the thickness of the first layers 111, 112, 113, 114 are increased. The first layers 111, 112, 113, 114 absorb more effectively the stress, which is increased according to the height from the base substrate 201.

According to exemplary embodiments of the present invention, organic layers and inorganic layers of a blocking layer, which is formed on a base substrate, have continuously changing component ratio according to a height of the base substrate in manufacturing a flexible substrate. Thus, a discontinuous area does not exist between the organic layer and the inorganic layer of the blocking layer. The adhesive power between the organic layer and the inorganic layer may be increased. Thus, the blocking layer blocking moisture or oxygen effectively may be formed on the base substrate of the flexible substrate.

In addition, the organic layer of the blocking layer is formed thicker as the height from the base substrate is increased. The crack of the substrate may be prevented more effectively when the flexible substrate is bent. Thus, moisture or oxygen is blocked effectively.

The foregoing is illustrative of the present invention and is not to be construed as limiting thereof. Although a few exemplary embodiments of the present invention have been described, those skilled in the art will readily appreciate that many modifications are possible in the exemplary embodiments without materially departing from the present invention.

What is claimed is:

1. A method for manufacturing a display substrate comprising:
forming a plastic base substrate; and
forming a blocking layer blocking moisture and oxygen on at least one surface of the plastic base substrate by depositing a first material and a second material different from the first material.

2. The method for manufacturing of claim 1,
wherein a component ratio of the first material to the second material is changed according to a height of the plastic base substrate.

3. The method for manufacturing of claim 2, further comprising:
a first layer having the first material and a second layer having the second material, and
wherein the first layer and the second layer are formed alternatingly.

4. The method for manufacturing of claim 3,
wherein the first material comprises organic material and the second material comprises inorganic material.

5. The method for manufacturing of claim 4,
wherein the first material comprises polyacrylate, polyethylene naphthalate (PEN) or polyethylene terephthalte (PET).

6. The method for manufacturing of claim 4, wherein the second material comprises silicon oxide (SiO₂) or aluminum oxide (Al₂O₃).

7. The method for manufacturing of claim 4,
wherein the first material and the second material are supplied from at least two more sources respectively, and
the component ratio of the first material to the second material is adjusted by controlling the sources.

8. The method for manufacturing of claim 7,
wherein the blocking layer is formed by a sputtering method, and
the blocking layer is formed by sputtering the first material and the second material simultaneously.

9. The method for manufacturing of claim 7,
wherein the blocking layer is formed by a chemical vapor deposition (CVD) method, and
the blocking layer is formed by adjusting the component ratio of the first material to the second material.

10. The method for manufacturing of claim 4,
wherein the plastic base substrate is moved along a first direction,
a plurality of sources are disposed along the first direction, and
the first material and the second material are supplied from a plurality of the sources.

11. The method for manufacturing of claim 10,
wherein the blocking layer is formed by a sputtering method, and
the sources supply the first material and the second material alternatingly.

12. The method for manufacturing of claim 10,
wherein the blocking layer is formed by a chemical vapor deposition (CVD) method, and
the sources supply the first material and the second material alternatingly.

13. The method for manufacturing of claim 10,
wherein the sources are disposed spaced apart from each other by different distances,
and each of the distances is increased according to each of thicknesses of the first layer and the second layer.

14. The method for manufacturing of claim 4,
wherein the first layer is formed substantially thicker than the second layer.

15. The method for manufacturing of claim 4,
wherein thicknesses of the first layer are constant, and
thicknesses of the second layer are increased according to a height of the plastic base substrate.

16. A display substrate comprising:
a plastic base substrate; and
a blocking layer formed on at least one surface of the plastic base substrate and having a first layer and a second layer alternatingly, and
wherein the first layer and second layer each comprise a first material and a second material and the ratio between the first material and the second material differs continuously throughout the thickness of the layers.

17. The display substrate of claim 16,
wherein the first material comprises organic material and the second material comprises inorganic material.

18. The display substrate of claim 17,
wherein the first material comprises polyacrylate, polyethylene naphthalate (PEN) or polyethylene terephthalte (PET).

19. The display substrate of claim 17,
wherein the second material comprises silicon oxide (SiO₂) or aluminum oxide (Al₂O₃).

20. The display substrate of claim 17,
wherein the first layer is formed substantially thicker than the second layer.

21. The display substrate of claim 17,
wherein thicknesses of the first layer are constant, and
thicknesses of the second layer are increased according to a height of the plastic base substrate.

22. A method for manufacturing a display substrate comprising:
forming a plastic base substrate;
depositing a first material on at least one surface of the base substrate without depositing a second material creating a first layer composed entirely of the first material;
simultaneously depositing the first and second materials onto the first layer creating an intermediate layer comprising both the first and second materials; and
depositing the second material on the intermediate layer without depositing the first material creating a second layer comprised entirely of the second material,
wherein the first material and the second material are distinct materials, and
wherein the first, intermediate, and second layers together comprise a blocking layer blocking moisture and oxygen.
